(19) United States
(12) Patent Application Publication
(10) Pub. No.: US 2019/0244927 A1
(43) Pub. Date: Aug. 8, 2019

(54) COVER FILM AND APPLICATION THEREOF

(71) Applicant: TAIFLEX Scientific Co., Ltd., KAOHSIUNG (TW)

(72) Inventors: Sheng-Chin Lin, KAOHSIUNG (TW); Yao-Ming Wu, KAOHSIUNG (TW); Yen-Hsiang Chen, KAOHSIUNG (TW); Yi-Ming Chen, KAOHSIUNG (TW)

(21) Appl. No.: 15/942,583

(22) Filed: Apr. 2, 2018

(30) Foreign Application Priority Data
Feb. 7, 2018 (TW) 107104265

(51) Int. Cl. H01L 23/00; C09D 5/34; C09D 179/08; C08G 73/10

(52) U.S. Cl. CPC H01L 24/29; H01L 2224/05684; H01L 24/83; H01L 24/32; H01L 24/73; H01L 24/92; C09D 5/34; C09D 179/085; C08G 73/1042; C08G 73/1085; C08G 73/1082; H01L 2224/2919; H01L 2224/2744; H01L 2924/20104; H01L 2224/27003; H01L 2924/20103; H01L 2224/73204; H01L 2224/32225; H01L 2924/07025; H01L 2924/20105; H01L 2924/20106; H01L 2224/9221; H01L 24/16; H01L 2224/16227; H01L 2224/02373; H01L 2224/05569; H01L 2224/12105; H01L 2224/0401; H01L 2224/05639; H01L 2224/05647; H01L 24/27

(57) ABSTRACT

A cover film includes a release layer and a polyimide layer disposed on the release layer. The polyimide layer includes an inner surface and an outer surface opposite to the inner surface. The outer surface is exposed to the atmosphere, and the polyimide layer is formed from a reaction of a polyimide composition made of diamine monomer and tetracarboxylic dianhydride monomer. The polyimide layer further includes a cross-linker and an initiator. The diamine monomer is an aliphatic diamine monomer with a number of carbon greater than or equal to 36. A lowest viscosity of the polyimide layer is less than 20000 Pa·s when polyimide layer is under a temperature in a range of 60° C. to 160° C.

### BACKGROUND OF THE INVENTION

### 1. Field of the Invention

The present invention relates to a cover film and an application thereof.

### 2. Description of the Prior Art

As the growing of electronic industries, polyimide layer is widely used in industry because of its high thermal stability and high chemical resistance etc. Applications include protection layers of integrated circuit chips, insulation layer between metal layers, flexible printed circuit boards, packaging materials and so on. However, as the products in the fields of computer, communication, opto-electronics keep scaling down, materials with high property performance are required. Hence, several properties of polyimide layer still need to be improved, such as its dielectric property, hygroscopicity, and high rigidity due to its high Young's modulus. Besides, the polyimide layer used for conventional semiconductor packaging structure has disadvantages such as difficulty in lamination, high imidization temperature, and high volume shrinkage during imidization. Furthermore, in the case of using polyimide layer as the insulation layer between the conductive structures on the surface of the semiconductor devices, the conventional polyimide layer still cannot completely fill a spacing or hole with high aspect ratio (such as a via with aspect ratio higher than 2), which is still an important issue needed to be overcome.

### SUMMARY OF THE INVENTION

A cover film is provided in this invention, including a release layer and a polyimide layer disposed on the release layer. The polyimide layer includes an inner surface and an outer surface disposed opposite to the inner surface, and the outer surface is exposed to the atmosphere. The polyimide layer is formed from a reaction of a polyimide composition including diamine monomer and tetracarboxylic dianhydride monomer. The polyimide layer further includes a cross-linker and an initiator. The diamine monomer is selected from the group consisting of aliphatic diamine monomer with a number of carbon greater than or equal to 36. A lowest viscosity of the polyimide layer is less than 20000 Pa·s when the polyimide layer is under a temperature in a range from 60° C. to 160° C.

A method of manufacturing an insulation layer on a surface of a semiconductor device is further provided in this invention, including following steps: providing a first semiconductor device including a plurality of first conductive structures on the surface of the first semiconductor device first; directly contacting the first semiconductor device with the polyimide layer of the above-mentioned cover film; and performing a hot press process to make the polyimide layer fill into at least one of spacings between the first semiconductor structures such that the first conductive structures are surrounded by the polyimide layer. After the hot press process, remove the release layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cover film according to an embodiment of the present invention.

FIG. 2 to FIG. 4 are schematic diagrams illustrating a method of manufacturing the insulation layer on a surface of a semiconductor device by the cover film according to a first example of the present invention.

FIG. 5 is a schematic diagram illustrating a packaging structure manufactured by the cover film according to the first example of the present invention.

FIG. 6 to FIG. 8 are schematic diagrams illustrating a method of manufacturing the insulation layer on the surface of the semiconductor device by the cover film according to a second example of the present invention.

### DETAILED DESCRIPTION

The cover film and the method of manufacturing the insulation layer on the surface of the semiconductor in this present invention may be understood by reference to the following detailed description, taken in conjunction with the drawings as described below. It should be noted that the technical features in different embodiments described in the following can be replaced, recombined, or mixed with one another to constitute another embodiment without departing from the spirit of the present disclosure. Besides, to simplify and clarify the description, the same component of device would be labeled with the same symbol in the following, and the structure or process features known to one of ordinary skill in the art will not be redundantly described. It is noted that, for purposes of illustrative clarity, certain elements in various drawings may not be drawn to scale.

A cover film is provided in this invention, including a release layer and a polyimide layer disposed on the polyimide layer. The polyimide layer includes an inner surface and an outer surface disposed opposite to the inner surface, and the outer surface is exposed to the atmosphere. In other words, the cover layer in this invention may only include two layers, which are the release layer and the polyimide layer, and a surface of the polyimide layer opposite to the release layer is not covered by any other layer. Besides, the polyimide layer is formed from a reaction of a polyimide composition that includes tetracarboxylic dianhydride monomer, diamine monomer and monomer containing at least one of hydroxyl group, carboxyl group and double-bond (C═C) functional group. Besides, the polyimide layer may further include a residual cross-linker and a residual initiator. The diamine monomer of the polyimide composition may include one or more diamine monomers, and at least includes diamine monomer with long-chain aliphatic groups, such as aliphatic diamine monomer with a number of carbon greater than or equal to 36. Through using the aliphatic diamine monomers with a number of carbon greater than or equal to 36, the polyimide layer correspondingly made may have properties that a lowest viscosity of the polyimide layer is less than 20000 Pa·s when the polyimide layer is under a temperature in a range from 60° C. to 160° C. The formed polyimide layer can also have low dielectric constant, low dielectric loss, low hygroscopicity, low young's modulus and higher solubility accordingly. Each of the compositions mentioned above will be described in the following.

The above diamine monomers includes diamine monomers containing cyclohexane group, such as 4,4′-diaminodicyclohexyl methane (MBCHA), 1,3-diaminomethylcyclohexane, 1,4-diaminomethylcyclohexane, bis(aminomethyl)bicyclo[2.2.1]heptane and 4,4′-methylenebis(2-methylcyclohexylamine). In addition, the diamine monomers used for forming the polyimide layer through a reaction may further include other diamine monomers, such as 2,2′-bis[4-(4-aminophenoxy)phenyl]propane (BAPP), 4,4′-methylene dianiline, α,α′-bis(4-aminophenyl)-1,4-diisopropylbenzene, 4,4′-oxydianiline, 3,3′-dimethyl-4,4′-diaminobiphenyl and 1,4-Bis(4-aminophenoxy)benzene. Preferably, the above diamine monomers includes aliphatic diamine monomers with a number of carbon greater than or equal to 36, which are derived from dimer acid (with dimer structure) of unsaturated fatty acids such as oleic acid and so on.

The above polyimide composition may further include monomers containing at least one of hydroxyl group, carboxyl group and double-bond (C═C) functional group, wherein diamine monomer containing hydroxyl group, anhydride monomer containing carboxyl group, diamine monomer containing carboxyl group, and diamine monomer containing double-bond (C═C) functional group may be included. Besides, the above mentioned monomers may be used singly or in combination. It is worth to mention that, when the polyimide composition used for forming the polyimide layer includes hydroxyl group, carboxyl group or double-bond (C═C) functional groups, the solubility of the polyimide layer may be increased, and the polyimide layer may be further cross-linked.

To be more specific, diamine monomer containing hydroxyl group may include (but not limited to) 3,3′-Dihydroxy-4,4′-diamino-biphenyl (HAB); anhydride monomer containing carboxyl group may include (but not limited to) trimellitic acidanhydride (TMA); diamine monomer containing carboxyl group may include (but not limited to) 3,5-diaminobenzoic acid (DABZ) or methylene bis(anthranilic acid) (MBAA); diamine monomer containing double-bond (C═C) functional group may include (but not limited to) 2-vinyl-4,6-diamino-1,3,5-triazine or 2,4-diamino-6-(methacryloyloxy)ethyl-1,3,5-triazine. In an embodiment, monomers containing hydroxyl groups, carboxyl groups or double-bond (C═C) functional groups may be, for example, trimellitic anhydride or 3,5-diaminobenzoic acid.

In addition, the above tetracarboxylic dianhydride monomers used in the reaction of the polyimide composition for forming the polyimide layer may be any tetracarboxylic dianhydride monomer known to one of ordinary skill in the art. Specifically, the tetracarboxylic dianhydride monomer may include (but not limited to) bis-(3-phthalyl anhydride)ether (ODPA), 3,3′,4,4′-benzophenonetetracarboxylic dianhydride (BTDA), pyromellitic dianhydride (PMDA), 4,4′-(4,4′-isopropylidenediphenoxy)bis(phthalic anhydride) (BPADA) or 3,3′,4,4′-biphenyltetracarboxylic dianhydride (BPDA). To be more precise, the above mentioned tetracarboxylic dianhydride monomers may be used singly or in combination.

The polyimide layer in this invention may further include cross-linker and initiator. The cross-linker includes compounds containing epoxy group, isocyanate group or alkenyl group. Specifically, the cross-linker includes (but not limited to) phenol novolac type epoxy resin, naphthalene type epoxy resin, or bisphenolA type epoxy resin. In addition, the cross-linker containing epoxy group may be commercial products, such as CNE-200EL (manufactured by Chang Chun Group Co.), PNE-177 (manufactured by Chang Chun Group Co.), EPDXY 4700(DIC Co.) and ESCV-90CR (manufactured by Nippon Steel & Sumikin Chemical Co.); the cross-linker containing isocyanate group may be commercial products, such as Desmodur N 3600 (manufactured by Bayer Co.) and Desmodur VK10 (manufactured by Bayer Co.); the cross-linker containing alkene group includes triallyl isocyanurate (TAIC). The initiator includes peroxide or photoinitiator. Specifically, the initiator includes (but not limited) to benzoyl peroxide (BPO), tert-Butylhydroperoxide (TBH) or dilauroyl peroxide.

It is worth to mention that, the cross-linker in this invention may perform a crosslinking reaction with monomers containing hydroxyl group or monomers containing carboxyl group, and the initiator may help the crosslinking reaction of the double-bond (C═C) functional group in the monomers containing double-bond (C═C) functional group. In other words, if the above mentioned polyimide composition used for forming the polyimide layer includes monomers containing hydroxyl group or carboxyl group, than correspondingly add the cross-linker into the polyimide composition; and if the above mentioned polyimide composition used for forming the polyimide layer includes monomers containing double-bond (C═C) functional group, than correspondingly add the initiator and cross-linker containing double-bond (C═C) functional group into the polyimide composition. Accordingly, through monomers including monomer groups selected from the group consisting of hydroxyl group, carboxyl group or double-bond functional group, and the cross-linker or the initiator, the soluble polyimide composition and the polyimide layer made thereby may have excellent chemical resistance and heat resistance.

To sum up, the polyimide layer of the cover film in this invention is formed by the reaction of the polyimide composition including the above mentioned diamine monomers, monomers containing hydroxyl group, carboxyl group or double-bond (C═C) functional group, tetracarboxylic dianhydride monomer, and further include the above mentioned cross-linker and/or initiator, so as to perform crosslinking reaction. Besides, it is worth to mention that, a non-reacted cross-linker and/or a non-reacted initiator are further included in the polyimide layer, and therefore in the following hot press process, the polyimide layer may have certain flowability and a further polymerization may occur. In other words, the polyimide layer of the cover film in this invention is a prepolymer with relative low molecular weight. The polyimide composition in of the polyimide layer has not fully reacted with all of the cross-linker and initiator by crosslinking so that the molecular weight of the compound of the polyimide layer has not increased through crosslinking reaction. For example, the weight percentage of the above mentioned residual cross-linker and the initiator that are not fully bonded or cross-linked with the polyimide material is greater than 0 wt % but less than or equal to 50 wt % of the overall polyimide layer resin, but not limited thereto.

In addition, within the scope of this present invention, an additive may be added into the polyimide composition used for forming the polyimide layer if needed. The additive may include flame retardant agent, colorant, filler or combinations thereof. It is worth to mention that, the filler may include silicon dioxide or calcium carbonate, so as to increase the rheological property in the following process and the laminated flowability in the lamination process.

The polyimide layer of the cover film in this invention is formed by the reaction of the above polyimide composition. Detail reaction steps will be described in the following. First, dissolve the diamine monomer, monomer containing at least one of hydroxyl group, carboxyl group and double-bond (C═C) functional group, and tetracarboxylic dianhydride monomer in a solvent and then perform a reaction to form a polyamic acid solution. The solvent may be any kind of solvents known by one of ordinary skill in the art, including (but not limited to) methylbenzene, dimethylbenzene, cyclohexane, cyclohexanone, 1-Methyl-2-pyrrolidinone (NMP), dimethylacetamide or combination thereof. Wherein, the reaction time is in the range of 1 hour to 6 hours, and the solid content of the polyamic acid solution is in the range of 10% to 50%, but not limited thereto. Next, perform an imidization process to the polyamic acid solution so that a polyimide solution is formed. In this step, the processing temperature of the imidization is in the range of 160° C. to 200° C.; the processing time is in the range of 1 hour to 6 hours, and the solid content of the polyimide solution is in the range of 10% to 50%, but not limited thereto. Afterwards, add the above cross-linker or the above initiator into the polyimide solution, so as to form a polyimide mixture solution. In an embodiment, the polyimide mixture solution may include the soluble polyimide, cross-linker, initiator and solvent.

Next, the polyimide mixed solution is coated on the release layer, and a drying process for 3 minutes to 5 minutes under temperature in the range of 100° C. to160° C. is performed, so as to form the polyimide layer on the release layer. Wherein, the method of coating includes (but not limited to) blade coating, wire bar coating, or screen printing. In addition, the release layer may be a release film that can provide applicable support for the polyimide layer formed in the following steps and have excellent dimensional stability. The release layer may be semi-dull or matte, so that the surface roughness and the gloss of the polyimide layer formed in the following steps may be modified.

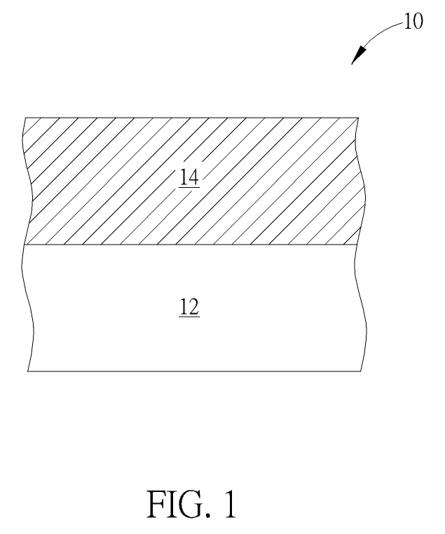

Accordingly, the cover film in this invention is obtained. The structure of the cover film is shown in FIG. 1. The cover film includes a release layer 12 and a polyimide layer 14 formed on the release layer 12. In the formation of the polyimide layer 14 of the cover film 10 in this invention, the polyimide mixture solution is first formed on the release layer 12 by coating, and then the heat process is performed. Therefore, comparing to the polyimide layer formed by the spin-coating of prior art, the polyimide layer in this invention may meet the requirement of film thickness with a wider range, such as 1 μm to 20 μm, but not limited thereto. Furthermore, by modifying the method of coating and the solid content of the polyimide mixture solution, a polyimide layer with thickness up to 100 μm may even be obtained, which is not applicable in the case of conventional spin coating method.

According to an embodiment of this invention, the above cover film can be used for manufacturing an insulation layer on the surface of the semiconductor device, especially for semiconductor devices with a plurality of protruding conductive structures, as described in the following.

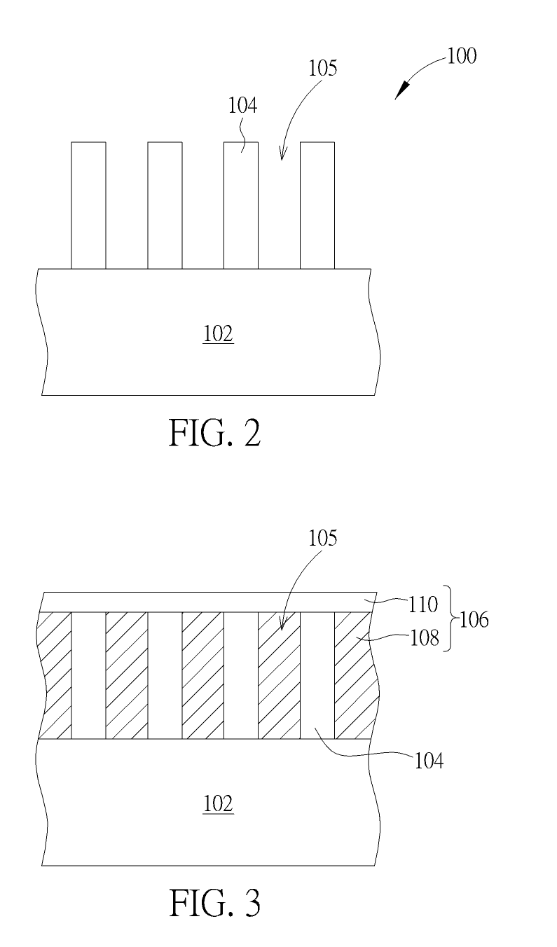

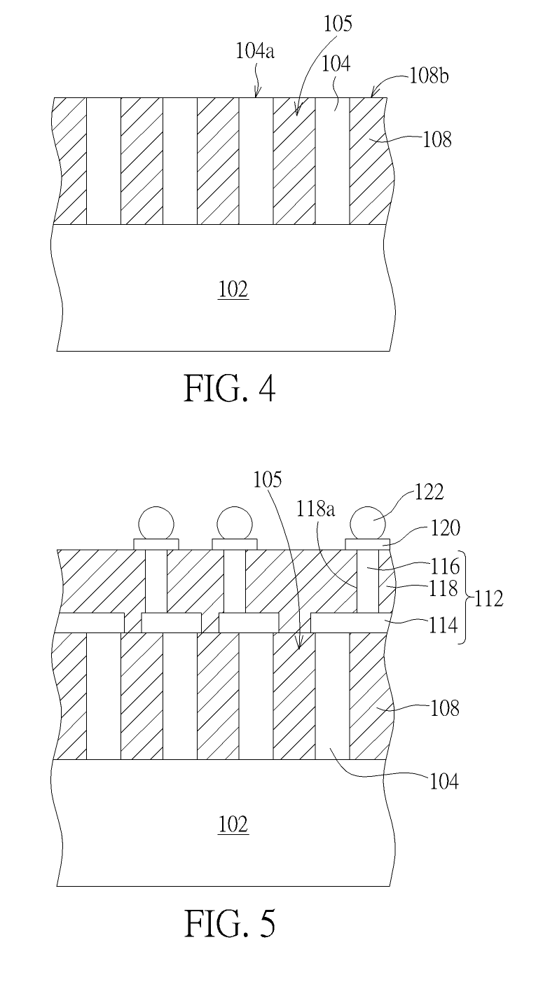

Please refer to FIG. 2 and FIG. 5. FIG. 2 to FIG. 4 are schematic diagrams illustrating a method of manufacturing the insulation layer on a surface of a semiconductor device by the cover film according to a first example of the present invention. FIG. 5 is a schematic diagram illustrating manufacturing a packaging structure by the cover film according to the first example of the present invention. As shown in FIG. 2, a first semiconductor device including a first portion 102 and a plurality of first conductive structures 104 disposed on the first portion 102 is provided, and at least one spacing 105 exists between the plurality of first conductive structures 104. The first portion 102 includes (but not limited to) chips, processors, dies, integrated circuits or other active/passive devices. The portion of the first semiconductor device other than the first conductive structure 104 all belongs to the first portion 102 (chips, processors, dies, integrated circuits). The first conductive structures 104 includes copper, silver, tungsten, an alloy of two or more of copper, silver, and tungsten, or a combination thereof, but not limited thereto. To be more precise, the first conductive structure 104 can be any conductive structure that meets the criterion of mechanical strength needed for a semiconductor device.

Next, please refer to FIG. 3, the first conductive structures 104 is subjected to directly contact with a polyimide layer 108 of a cover film 106 in this invention. And then, a hot press process is performed to the cover film 106, so as to make the polyimide layer 108 fill into at least one of the spacings 105 between the first conductive structures 104 such that the first conductive structures 104 are surrounded by the polyimide layer 108. Wherein, the hot press process is performed under a temperature in a range from 60° C. to 160° C., and thus a lowest viscosity of the polyimide layer is less than 20000 Pa·s. Accordingly, the polyimide layer has applicable flowability. After the hot press process, a solidification temperature in a range of 160° C. to 200° C. is provided, such that further reactions occur in the non-reacted cross-linker and the non-reacted initiator in the polyimide layer 108, and the polymer chains therein are cross-linked. Therefore, a thermosetting polyimide layer 108 is formed.

As mentioned above, since the method of manufacturing the insulation layer on the surface of the semiconductor device is achieved through a hot press process, the polyimide layer 108 of the cover film 106 can have applicable laminated flowability, such that the spacings 105 between the first conductive structures 104 with an aspect ratio greater than or equal to 3 can be fully filled. It is worth to mention that, the upper limit of the aspect ratio of the spacings 105 between the first conductive structures 104 that the cover film 106 can fill depends on a maximum strength that the first conductive structure 104 can take without being fractured.

Next, the release layer 110 of the cover film 106 is removed to expose an upper surface 104a of the first conductive structure, as the structure shown in FIG. 4. In this embodiment, after removing the release layer 110, such as by plasma etching or grinding, the upper surface 104a of the first conductive structure and the upper surface 108b of the polyimide layer become coplanar.

After performing the steps shown in FIG. 4, other conductive structures may further be formed on the first conductive structures 104 and the polyimide layer 108. Please refer to the following detailed introduction.

Referring to FIG. 5, after the above steps, a redistribution layer 112 may be formed on the polyimide layer 108, and the redistribution layer 112 is in contact with and electrically connected to the upper surface 104a of the first conductive structure. Wherein, the redistribution layer 112 includes at least one patterned conductive layer 114, at least one redistribution line 116, at least one dielectric layer 118 and at least one through-hole 118a, and the redistribution line 116 is disposed in the through hole 118a. In other words, the redistribution layer 112 may include a plurality of dielectric layers 118 and a plurality of corresponding patterned conductive layers 114, redistribution lines 116 and through-holes 118a, so as to redistribute the circuits.

In this embodiment, the dielectric layer 118 is formed by performing a hot press process to the polyimide layer 108 of the cover film 106 in this invention after. In FIG. 5, only one dielectric layer 118 and one patterned conductive layer 114 are illustrated, but not limited thereto. Afterwards, a plurality of conductive pads 120 separate to each other are selectively formed on the redistribution layer 112, and a solder ball 122 or a metal pillar bump is formed on each of the conductive pads 120, but not limited thereto. The conductive pads 120, which are disposed between the redistribution line 116 and the solder ball 122 may enhance functions such as adhesion, diffusion barrier, wettability or antioxidation, including under bump metallization (UBM) layer. From the above, the circuits in the first portion 102 are electrically connected to the first conductive structures 104, redistribution layers 112 and solder balls 122, each of the spacings 105 between first conductive structures 104 has an aspect ratio greater than or equal to 3 and is filled by the polyimide layer 108, the dielectric layer 118 may selectively use the polyimide layer 108 in this invention, and therefore a packaging structure is formed.

The cover film in this invention is not limited to the above embodiments. To compare the embodiments or the variant embodiments conveniently and simplify the description, the following description will detail the dissimilarities among different embodiments and variant embodiments and the identical features will not be redundantly described.

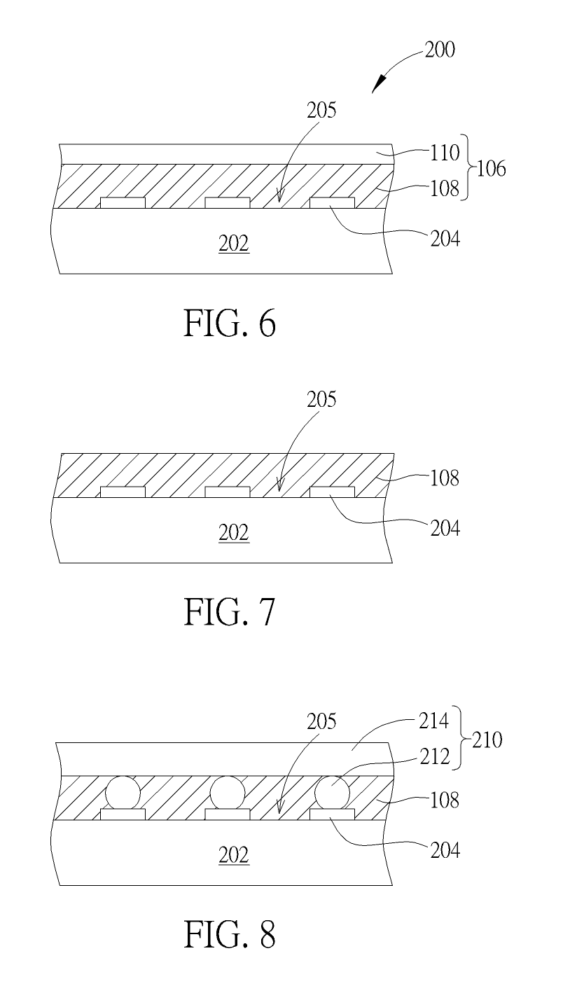

FIG. 6 to FIG. 8 are schematic diagrams illustrating a method of manufacturing the insulation layer on the surface of the semiconductor device by the cover film according to a second example of the present invention. In this application, the cover film is used for forming a flip chip packaging structure or a packaging structure manufacturing by hot press process. As shown in FIG. 6, a semiconductor device 200 is provided first, wherein the semiconductor device 200 includes a first portion 200 and a plurality of first conductive structures 204. The first semiconductor device 200 may include a substrate, wherein the substrate includes printed circuit board, interposer, silicon substrate or glass substrate, but not limited thereto. The first conductive structures 204 may be contact pads. Next, the first conductive structures 204 is subjected to directly contact with the polyimide layer 108 of the cover film 106, and then the hot press process to the cover film 106 is performed, so as to make the polyimide layer 108 fill into at least one of spacings 205 between the first conductive structures 204, and therefore the first conductive structures 204 are surrounded by the polyimide layer 108. As shown in FIG. 7, after the hot press process, a release layer 110 is removed. Next, as shown in FIG. 8, a second semiconductor device 210 including a second portion 214 and a plurality of second structures 212 disposed on the second portion 214 is provided, wherein the second conductive structures 212 are correspondingly disposed on the first conductive structures 204. The second portion 214 includes (but not limited to) chips, processors, dies, integrated circuits or other active/passive devices. For example, the second semiconductor device 210 may be the packaging structure of the first application in this invention, but not limited thereto. The first semiconductor device 200 and the second semiconductor device 210 are bonded together, such that the polyimide layer 108 between the first conductive structures 204 and the second conductive structures 212 are excluded and the first conductive structures 204 are electrically connected to the corresponding second conductive structures 212. It is worth to mention that, when first semiconductor device 200 is subjected to contact with the second semiconductor device 210, any bonding process known to one of ordinary skill in the art may be used, such as fusion bonding, metal thermal compression bonding and so on, but not limited thereto. The time of the hot press process or the time of the metal thermal compression bonding is within 180 seconds when the temperature is in the range of 200° C. to 300° C. In this application, the spacings 205 between the first conductive structures 204 and the second conductive structures 212 is filled by the polyimide layer 108 that has an excellent laminated flowability. After the hot press process, a curing temperature 160° C. to 200° C. is provided. For example, a pressure oven is used to exclude bubbles and make the cross-linker and the initiator in the polyimide layer 108 further produce reactions, such that the polymer chains are further cross-linked and a thermosetting polyimide layer 108 is formed.

To produce a polyimide layer that has excellent dielectric properties and low young's modulus and may be applicable in thinning process, a polyimide composition is provided in this invention. Thereafter, exemplary examples will be detailed as follows. In the following, exemplary examples and comparisons of the methods of manufacturing the cover film are detailed to further clarify the technical features in this invention.

The materials used for manufacturing the polyimide layer and cover film in examples 1-2 and comparison example 1 are listed below.

Tetracarboxylic dianhydride monomer: pyromellitic dianhydride (PMDA)

Diamine monomer with long chain aliphatic groups: Priamine™ 1074-Dimer diamine (manufactured by Croda Co.), wherein the number of carbons in is 36.

Monomers selected from the group consisting of hydroxyl groups, carboxyl groups and double-bond (C═C)functional groups: 3,5-diaminobenzoic acid (DABZ, manufactured by Jinyutech Co.), 4,4′-diaminodicyclohexyl methane (MBCHA, manufactured by TCI Co.), 2-vinyl-4,6-diamino-1,3,5-triazine (VT, manufactured by Shikoku Chemicals Co.)

Other diamine monomers: 2,2′-bis[4-(4-aminophenoxy)phenyl]propane (BAPP, manufactured by Tong-Sing Co.)

Cross-linker: tris(2,3-epoxy propyl) isocyanurate (TEPIC); triallyl isocyanurate (TAIC)

Initiator: benzoyl peroxide (BPO, manufactured by Keeneyes Co.)

Solvent: cyclohexanone (manufactured by Shiny Chemical Co.); 1-methyl-2-pyrrolidinone (NMP, manufactured by Taimax Co.)

Release film: PET-50-SHP-A (manufactured by Fujiko Co.)

### EXAMPLE 1

First, dissolve 10 moles of pyromellitic dianhydride (PMDA) monomers, 6 moles of Priamine™ 1074-Dimer diamine and 3 moles of 4,4′-diaminodicyclohexyl methane (MBCHA) and 0.5 moles of 2-vinyl-4,6-diamino-1,3,5-triazine (VT) into a mixture solution of cyclohexanone and 1-methyl-2-pyrrolidinone (NMP). Next, perform a reaction to the mixture solution for 2 hours and produce a polyamic acid solution that has a solid content 20 wt %. Next, perform an imidization process to the polyamic acid solution at 180° C. for 3 hours to form polyimide solution. Afterwards, add 5 grams of tris(2,3-epoxy propyl) isocyanurate (TEPIC), 5 grams of triallyl isocyanurate (TAIC) and 5 grams of benzoyl peroxide (BPO) into the polyimide solution that has 100 grams solid content to prepare the polyimide mixture solution. Next, coat the polyimide mixture solution is coated on the release layer, then perform a drying process for 3 minutes under 160° C., so as to form the polyimide layer of this invention on the release layer. Wherein, the polyimide layer is a prepolymer that has not fully performed the crosslinking reaction with all of the cross-linker and the initiator and the molecular weight of the polyimide layer is not increased thereby.

### EXAMPLE 2

The method of manufacturing the cover film in this example is similar to example 1, the difference is that in this example 6 moles of P1074 is modified to 9 moles of P1074 and no MBCHA is added.

### COMPARISON EXAMPLE 1

The method of manufacturing the cover film in this comparison is similar to example 1, the difference is that in this comparison 6 moles of Priamine™ 1074-Dimer diamine is modified to 3 moles of Priamine™ 1074-Dimer diamine and 3 moles 4,4′-diaminodicyclohexyl methane (MBCHA) is modified to 6 moles. Besides, the polyimide formed by performing imidization reaction to the polyamic acid solution in this comparison example at 180° C. for 3 hours has low solubility, in other words, the polyimide formed after performing imidization reaction can't form polyimide mixture solution with the cross-linker and the initiator, therefore the polyimide can't be coated on the release layer. Therefore, the polyimide layer in comparison 1 is directly formed by performing imidization reaction to the polyamic acid solution.

Afterwards, the Young's modulus, temperature flow curves, dielectric constant, dielectric losses, and hygroscopicity of the polyimide layer are measured in the example 1 and example 2. The results are listed below.

According to ASTM-D638, type V specimen is used to measure the tensile strength, Young's modulus and elongation. When performing a tensile strength test, the relation between the tensile stress and the elongation of the specimen are recorded until the specimen is fractured. In Table 1, the tensile strengths of the polyimide layer are derived from dividing the tensile force applied to the specimen by the original cross sectional area of the specimen. The elongation of the specimen is derived from subtracting the original length of the polyimide layer specimen from the length when the polyimide layer specimen is fractured and then divide the subtracted value thereby by the original length of the specimen. The Young's modulus is derived from the tensile force and corresponding elongation, lower Young's modulus means lower rigidity of the polyimide layer.

According to IPC-TM-650 2.5.5.5.1B, a Vector Network Analyzer (ZVB20, manufactured by Rohde & Schwarz Co.) is used to measure the dielectric constants and the dielectric losses of example 1, example 2 and comparison example 1. The frequency used is 10 GHz. In Table 1, lower dielectric layer means better polyimide layer.

Next, a rotational rheometer (DHR 2, manufactured by TA Instrument Co.) is used to measure the temperature flow curves of example 1 and example 2, and then derive the lowest viscosity, as shown in Table 1.

In addition, the filling ability in Table 1 is defined as below. First, the polyimide layer under 130° C. is dryed, and then a vacuum quick press process is performed to the polyimdie layer between lines with a line spacing of 3 mils for 3 minutes at a pressure of 5 kgf/cm². Thereafter, how the polyimide layer fills the spacings between circuit lines is observed. When no bubble is occured in the spacing between the two adjacent circuit lines, the filling ability is defined as passed.

TABLE 1

| | | | Comparison |
|---|---|---|---|
| | Example 1 | Example 2 | example 1 |
| PMDA(mol) | 10 | 10 | 10 |
| P1074(mol) | 6 | 9 | 3 |
| MBCHA(mol) | 3 | 0 | 6 |
| VT(mol) | 0.5 | 0.5 | 0.5 |
| Tensile | 58 | 52 | insoluble |
| strength (MPa) | | | |
| Young's modulus | 1.5 | 0.8 | |
| (GPa) | | | |
| Elongation(%) | 50 | 80 | |
| Viscosity | 15000 | 12000 | |
| (Pa · s)(at | | | |
| 120° C.) | | | |
| Dielectric | 2.7 | 2.7 | |
| constant | | | |
| Dielectric loss | 0.006 | 0.004 | |
| Filling ability | Pass | Pass | |

According to Table 1, the polyimide in example 1 and example 2 is soluble, therefore the polyimide can be coat on the release layer and then dried at 160° C. for 3 minutes to form polyimide layer, so as to obtain the cover film of this invention. Besides, the polyimide layers of example 1 and example 2 can pass the filling ability test, and the tensile strength, Young's modulus, elongation, dielectric constant and dielectric loss of the polyimide layers of example 1 and example 2 are acceptable. Therefore, the polyimide layers of example 1 and example 2 can further be used to form the insulation layer on the surface of the semiconductor device by the methods provided above. Furthermore, the polyimide layers of example 1 and example 2 have excellent laminated flowability at the hot press temperature, therefore the polyimide layer and the example method of this invention can replace flip-chip process, in which conventional underfill material is dispensed between the chip and the substrate and then be forced to fill therebetween by capillarity. Therefore, comparing to the conventional underfill material, the example method of this invention has better filling ability and, lower processing time and less bubbles occurred. Moreover, the polyimide layer of the cover film of this invention can be filled into the spacings that have an aspect ratio equal to or more than 3 by the hot press process. Hence, the polyimide layer in this invention may be used as dielectric layer, packaging material, and underfill material in packaging structures of semiconductor devices.

Those skilled in the art will readily observe that numerous modifications and alterations of the device and method may be made while retaining the teachings of the invention. Accordingly, the above disclosure should be construed as limited only by the metes and bounds of the appended claims.

1. A cover film, comprising:
a release layer; and
a polyimide layer disposed on the release layer, wherein the polyimide layer comprises an inner surface and an outer surface disposed opposite to the inner surface, the outer surface is exposed to the atmosphere, and the polyimide layer is formed from a reaction of a polyimide composition comprising diamine monomer and tetracarboxylic dianhydride monomer, wherein the diamine monomer is selected from the group consisting of aliphatic diamine monomer with a number of carbon greater than or equal to 36, and a lowest viscosity of the polyimide layer is less than 20000 Pa·s when the polyimide layer is under a temperature in a range from 60° C. to 160° C.

2. The cover film according to claim 1, wherein the polyimide layer further comprises a cross-linker not bonding to the polyimide composition and an initiator.

3. The cover film according to claim 1, wherein the polyimide composition used for forming the polyimide layer further comprises monomers containing at least one of hydroxyl group, carboxyl group and double-bond (C═C) functional group.

4. The cover film according to claim 1, wherein the diamine monomer used for forming the polyimide layer comprises 4,4′-diaminodicyclohexyl methane.

5. The cover film according to claim 1, wherein the polyimide layer can be filled into a spacing that has an aspect ratio of 3 during a hot press process under a temperature range of 60° C. to 160° C.

6. The cover film according to claim 1, wherein the outer surface of the polyimide layer is not covered by any other layer.

7. The cover film according to claim 1, wherein the cross-linker comprises compounds including epoxy group, isocyanate group or olefin group, and the initiator comprises peroxide.

8. A method of manufacturing an insulation layer on a surface of a semiconductor device, comprising:
providing a first semiconductor device comprising a first portion and a plurality of first conductive structures disposed on the first portion;
directly contacting the first conductive structures with the polyimide layer of the cover film according to claim 1;
performing a hot press process to make the polyimide layer fill into at least one of spacings between the first semiconductor structures such that the first conductive structures are surrounded by the polyimide layer; and
after performing the hot press process, removing a release layer and solidifying the insulation layer under a temperature in a range of 160° C. to 200° C.

9. The method of manufacturing the insulation layer on the surface of a semiconductor device according to claim 8, wherein a temperature of the hot press process is in a range of 60° C. to 160° C.

10. The method of manufacturing the insulation layer on the surface of a semiconductor device according to claim 8, wherein an aspect ratio of the spacings between the first conductive structures is greater than or equal to 3.

11. The method of manufacturing the insulation layer on the surface of a semiconductor device according to claim 8, wherein the first semiconductor device comprises chip.

12. The method of manufacturing the insulation layer on the surface of a semiconductor device according to claim 11, wherein the first conductive structures comprises copper, silver, tungsten, an alloy of two or more of copper, silver, and tungsten, or a combination thereof.

13. The method of manufacturing the insulation layer on the surface of a semiconductor device according to claim 8, wherein after removing the release layer, the first conductive structures are clad in the polyimide layer, and after removing the release layer, the manufacturing method further comprises:
providing a second semiconductor device comprising a second portion and a plurality of second conductive structures disposed on the second portion, wherein the second conductive structures are disposed corresponding to the first conductive structures; and
connecting the first semiconductor device and the second semiconductor device, so as to remove the polyimide layer between the first semiconductor device and the second semiconductor device and to make the first conductive structures be electrically connected to the corresponding second conductive structures.

14. The method of manufacturing insulation layer on the surface of a semiconductor device according to claim 13, wherein the first portion is a printed circuit board, an interposer, a silicon substrate or a glass substrate.

15. The method of manufacturing the insulation layer on the surface of a semiconductor device according to claim 13, wherein the second semiconductor device comprises a chip.
